(19) United States
(12) Patent Application Publication
(10) Pub. No.: US 2021/0143345 A1
(43) Pub. Date: May 13, 2021

(54) FLEXIBLE BASE MATERIAL, FLEXIBLE SUBSTRATE, AND PREPARATION METHOD THEREOF

(71) Applicants: BEIJING BOE OPTOELECTRONICS TECHNOLOGY CO., LTD., Beijing (CN); BOE TECHNOLOGY GROUP CO., LTD, Beijing (CN)

(72) Inventors: Yifeng QIN, Beijing (CN); Kai LU, Beijing (CN); Yongshan ZHOU, Beijing (CN); Dongsheng HUANG, Beijing (CN)

(21) Appl. No.: 16/630,987

(22) PCT Filed: Jul. 8, 2019
(86) PCT No.: PCT/CN2019/095105

§ 371 Date: Jan. 14, 2020

(30) Foreign Application Priority Data
Aug. 31, 2018 (CN) 201811015610.3

(51) Int. Cl. H01L 51/00; C08K 9/12; C08K 3/04; H01F 1/01

(52) U.S. Cl. CPC H01L 51/0097; C08K 9/12; B82Y 25/00; H01F 1/015; C08K 3/041

(57) ABSTRACT

Embodiments of the present disclosure provide a flexible base material, a preparation method of the flexible base material, a flexible substrate and a preparation method of the flexible substrate. The flexible base material includes: a host flexible material; and carriers dispersed in the host flexible material and having magnetic particles adsorbed thereon, and the carriers have organophilic functional groups on their surface.

The present application claims priority of Chinese Patent Application No. 201811015610.3 filed on Aug. 31, 2018, the present disclosure of which is incorporated herein by reference in its entirety as part of the present disclosure.

### TECHNICAL FIELD

Embodiments of the present disclosure relate to a flexible base material, a preparation method of a flexible base material, a flexible substrate and a preparation method of a flexible substrate.

### BACKGROUND

Circuit structures made on a flexible base substrate have characteristics of small size, light weight, and flexible. The circuit structures are used in touch screens, thin film transistors, organic light-emitting diodes, flexible printed circuits, and biological or medical sensors and so on.

With the rapid development of organic photoelectronic technology, the photoelectronic products, such as, organic solar cells, sensors, and thin film transistors and so on are gradually grow up, and substantially improve people's lives. Meanwhile, the widespread use of photoelectronic technology in various field of social life has created increasing market values.

For example, plastic substrates, instead of common glass substrates, are used in organic light emitting diodes (OLEDs). With the help of the film encapsulating technology, in a case that plastic substrates are used, it is allowed to attach a protective film onto a back surface of a panel so that the panel becomes flexible and not easy to be broken.

### SUMMARY

At least one embodiment of the present disclosure provides a flexible base material, and the flexible base material comprises: a host flexible material; and carriers dispersed in the host flexible material and having magnetic particles adsorbed thereon; and the carriers have organophilic functional groups on their surface.

For example, in the flexible base material provided by at least one embodiment of the present disclosure, the host flexible material comprises: polyetheretherketone, polyarylester, fluorinated polyimide, polyimide, polycarbonate, polyethylene, polyacrylate, polyarylate, polyetherimide, polyethersulfone, polyethylene terephthalate, polypropylene, polysulfone, polymethylmethacrylate, cellulose triacetate, cycloolefin polymer, cellulose acetate propionate, polyethylene naphthalene dicarboxylate, polyphenylene sulfide, or cycloolefin copolymer.

For example, in the flexible base material provided by at least one embodiment of the present disclosure, the organophilic functional groups comprise at least one of amino, mercapto, vinyl, epoxy, cyano, carboxyl, and methacryloyloxy.

For example, in the flexible base material provided by at least one embodiment of the present disclosure, the magnetic particles comprise an elemental metal or alloy of iron, cobalt, or nickel.

For example, in the flexible base material provided by at least one embodiment of the present disclosure, the magnetic particles are spherical or near-spherical.

For example, in the flexible base material provided by at least one embodiment of the present disclosure, the carriers are made of at least one of carbon black, activated carbon, and carbon nanotube.

At least one embodiment of the present disclosure further provides a preparation method of a flexible base material, and the preparation method comprises: forming carriers having magnetic particles adsorbed thereon; and dispersing the carriers having magnetic particles adsorbed thereon into a host flexible material; and before dispersing the carriers having magnetic particles adsorbed thereon into the host flexible material, the preparation method further comprises: subjecting the carriers to a surface treatment thereby allowing the carriers to have organophilic functional groups on their surfaces.

For example, in the preparation method provided by at least one embodiment of the present disclosure, the forming carriers having magnetic particles adsorbed thereon comprises: dispersing the magnetic particles into a first solvent to form a dispersion of the magnetic particles; dispersing the carriers into the dispersion of the magnetic particles to adsorb the magnetic particles; separating the carriers from dispersion liquor in the dispersion of the magnetic particles; and drying the carriers to obtain the carriers having magnetic particles adsorbed thereon.

For example, in the preparation method provided by at least one embodiment of the present disclosure, before forming the carriers having the magnetic particles adsorbed thereon, the preparation method further comprises: modifying the carriers to expose adsorbing channels inside the carriers.

For example, in the preparation method provided by at least one embodiment of the present disclosure, the modifying the carriers to expose adsorbing channels inside the carriers comprises: dispersing the carriers into an acidic solvent; separating the carriers from the acidic solvent; washing the carriers until a stable pH is achieved; and drying the carriers to obtain modified carriers.

For example, in the preparation method provided by at least one embodiment of the present disclosure, the subjecting the carriers to a surface treatment thereby allowing the carriers to have organophilic functional groups on their surfaces comprises: dispersing the carriers into a second solvent; heating the second solvent having the carriers dispersed therein; adding a solution comprising the organophilic functional groups to the second solvent; separating the carriers; and drying the carriers to obtain the carriers having the organophilic functional groups on their surfaces.

At least one embodiment of the present disclosure further provides a flexible substrate, and the flexible substrate comprises: a flexible base made of the flexible base material of any one of the above mentioned embodiments; and a thin film transistor formed on the flexible base substrate.

For example, in the flexible substrate provided by at least one embodiment of the present disclosure, an organic insulating layer is arranged between the flexible base substrate and the thin film transistor.

For example, in the flexible substrate provided by at least one embodiment of the present disclosure, an inorganic insulating layer is arranged between the organic insulating layer and the thin film transistor.

At least one embodiment of the present disclosure further provides a preparation method of a flexible substrate, and the preparation method comprises: providing a glass substrate; forming a magnetic layer on the glass substrate; forming a flexible base substrate on the magnetic layer by using the flexible base material of any one of the above mentioned embodiments; and forming a thin film transistor on the flexible base substrate; treating the magnetic layer and the flexible base substrate to eliminate a magnetic force between the magnetic layer and the flexible base substrate; and removing the glass substrate and the magnetic layer to obtain the flexible substrate.

For example, in the preparation method provided by at least one embodiment of the present disclosure, materials of the magnetic layer comprise at least one of SmCo magnet, NdFeB magnet, ferrite magnet, AlNiCo magnet and FeCrCo magnet.

For example, in the preparation method provided by at least one embodiment of the present disclosure, the treating the magnetic layer and the flexible base substrate to eliminate the magnetic force between the magnetic layer and the flexible base substrate comprises: eliminating the magnetic force between the magnetic layer and the flexible base substrate by means of applying an external force, heating, or applying an electric field.

For example, the preparation method provided by at least one embodiment of the present disclosure further comprises: forming an organic insulating layer between the flexible base substrate and the thin film transistor.

For example, the preparation method provided by at least one embodiment of the present disclosure further comprises: forming an inorganic insulating layer between the organic insulating layer and the thin film transistor.

### BRIEF DESCRIPTION OF THE DRAWINGS

In order to clearly illustrate the technical solution of the embodiments of the present disclosure, the drawings of the embodiments will be briefly described. It is apparent that the described drawings are only related to some embodiments of the present disclosure and thus are not limitative of the present disclosure.

FIG. 1 is a schematic component view of a flexible base material;

FIG. 2 is a schematic component view of a flexible base material provided by an embodiment of the present disclosure;

FIG. 3 is an enlarged schematic structural view of carriers having magnetic particles adsorbed thereon provided by an embodiment of the present disclosure;

FIG. 4 is a flowchart of a preparation method of a flexible base material provided by an embodiment of the present disclosure;

FIG. 5 is a schematic view of a flexible substrate provided by an embodiment of the present disclosure;

FIG. 6 is a schematic view of a cross-sectional structural of a flexible substrate provided by an embodiment of the present disclosure;

FIG. 7 is a schematic view of a cross-sectional structural of a flexible substrate provided by another embodiment of the present disclosure;

FIG. 8 is a flowchart of a preparation method of a flexible substrate provided by an embodiment of the present disclosure; and

FIG. 9 a schematic view of applying an electric field to eliminate a magnetic force between the magnetic layer and the flexible base provided by an embodiment of the present disclosure.

### DETAILED DESCRIPTION

In order to make objects, technical details and advantages of embodiments of the present disclosure clear, the technical solutions of the embodiments will be described in a clearly and fully understandable way in connection with the related drawings. It is apparent that the described embodiments are just a part but not all of the embodiments of the present disclosure. Based on the described embodiments herein, those skilled in the art can obtain, without any inventive work, other embodiment(s) which should be within the scope of the present disclosure.

Unless otherwise defined, all the technical and scientific terms used herein have the same meanings as commonly understood by one of ordinary skill in the art to which the present disclosure belongs. The terms “first,” “second,” etc., which are used in the description and claims of the present disclosure, are not intended to indicate any sequence, amount or importance, but distinguish various components. The terms “comprises,” “comprising,” “includes,” “including,” etc., are intended to specify that the elements or the objects stated before these terms encompass the elements or the objects listed after these terms as well as equivalents thereof, but do not exclude other elements or objects. The phrases “connect”, “connected”, etc., are not intended to define a physical connection or a mechanical connection, but may comprise an electrical connection which is direct or indirect. The terms “on,” “under,” “right,” “left” and the like are only used to indicate relative position relationship, and in a case that the position of an object is described as being changed, the relative position relationship may be changed accordingly.

It should be indicated that, structural sizes involved in the embodiments of the present disclosure are usually on order of millimeter (mm), micron (μm), submicron (100 nm to 1.0 μm), or nanometer (nm), and thus the sizes of various structures in the drawings of the embodiments of the present disclosure are enlarged and do not represent the actual sizes.

Currently, the production of flexible electronic devices requires: providing a glass substrate, forming a flexible base substrate on the glass substrate, and then forming various functional structures on the flexible base substrate. After completing the formation of the various functional structures, a laser polar sintering is required to achieve the separation of the flexible base substrate from the glass substrate. However, the laser irradiation has an impact on an active layer of a thin film transistor that cannot be ignored, and in the process of separating the flexible base substrate from the glass substrate by the laser irradiation, it is prone to cause the problem of carbonization of the flexible base substrate.

The inventor of the present disclosure finds that it is possible to fabricate a magnetic layer on a glass substrate; and then form a flexible base substrate on the magnetic layer so that the flexible base substrate is both magnetic and flexible, in which the magnetic layer on the glass substrate is closely attached to the flexible base substrate by a magnetic force; and then separate the glass substrate from the flexible base substrate by means of applying an external force, heating or demagnetizing, which avoids adverse effects on the active layer and the flexible base substrate caused by the laser irradiation separation, and the whole process is easy to operate and produces no effect on the functional layers.

The magnetic layer is formed on a surface of the glass substrate firstly in an embodiment of the present disclosure, and then an intermediate organic layer containing magnetic particles is formed, optionally, an additional flexible layer is formed on a surface of the intermediate organic layer (it should be noted that, the intermediate organic layer containing the magnetic particles is used as the flexible base substrate, or a combination of the intermediate organic layer containing the magnetic particles and the flexible layer is used as the flexible base substrate), and finally various functional layers are fabricated on the flexible base substrate. The method achieves the fixation of a flexible substrate to the glass substrate through a magnetic interaction between the intermediate organic layer containing the magnetic particles and the magnetic layer on the glass substrate. Moreover, in order to enhance the magnetic force, the magnetic particles contained in the intermediate organic layer are adsorbed and fixed onto modified carriers, and then the carriers containing a large number of magnetic particles are mixed into the intermediate organic layer.

For example, FIG. 1 is a schematic component view of a flexible base material. The flexible base material 10 only comprises a host flexible material, and the flexible base material is only flexible and non-magnetic. After a flexible base substrate made of the flexible base material is formed on the glass substrate and various functional structures are formed on the flexible base substrate, the glass substrate and the flexible base substrate have to be separated by means of laser polar sintering, in this way, the problems of affecting the active layer and carbonizing the flexible substrate mentioned above are occurred.

At least one embodiment of the present disclosure provides a flexible base material. For example, FIG. 2 is a schematic component view of a flexible base material provided by an embodiment of the present disclosure. As illustrated in FIG. 2, the flexible base material 20 comprises: a host flexible material 21, and carriers 23 dispersed in the host flexible material 21 and having magnetic particles 22 adsorbed thereon, and the carriers 23 have organophilic functional groups on their surfaces 24.

For example, the carriers 23 are homogeneously or inhomogeneously dispersed in the host flexible material 21; the magnetic particles 22 are homogeneously or inhomogeneously adsorbed onto the carriers 23. Optionally, the carriers 23 have adsorbing pores, and the magnetic particles 22 are adsorbed in the adsorbing pores of the carriers 23; and the organophilic functional groups 24 are homogeneously or inhomogeneously distributed on the surface of the carriers 23.

For example, in the flexible base material, a mass percent of the carriers 23 is from about 20% to 40%, a mass percent of the magnetic particles is from about 5% to 10%, and a mass percent of the host flexible material is from about 55% to 70%.

For example, in the flexible base material, the mass percent of the carriers 23 is 35%, the mass percent of the magnetic particles is 8%, and the mass percent of the host flexible material is 57%.

For example, the host flexible material 21 comprises polyetheretherketone, polyarylester, fluorinated polyimide, polyimide (PI), polycarbonate (PC), polyethylene, polyacrylate, polyarylate, polyetherimide, polyethersulfone, polyethylene terephthalates (PET), polypropylene (PP), polysulfone (PSF), polymethylmethacrylate (PMMA), cellulose triacetate (TAC), cycloolefin polymer (COP), cellulose acetate propionate (CAP), polyethylene naphthalene dicarboxylate (PEN), polyphenylene sulfide (PPS), or cycloolefin copolymer (COC).

It should be noted that, the host flexible material 21 comprises, but not limited to, any one of the above-mentioned materials or any combination thereof, and the host flexible material 21 may further comprise other suitable material(s).

For example, the organophilic functional groups comprise at least one of amino, mercapto, vinyl, epoxy, cyano, carboxyl, and methacryloyloxy. For example, the organophilic functional groups comprise any one of the above mentioned groups or combination, or any combination thereof.

The dispersibility of the carriers 23 in the host flexible material is increased due to the above mentioned organophilic functional groups on the surfaces of the carriers 23, which further increases the dispersibility of the magnetic particles 22 in the host flexible material 21, so that the formed flexible base substrate has a better magnetic property.

For example, the magnetic particles comprise an elemental metal of iron, cobalt, or nickel, or an alloy of at least two of iron, cobalt, and nickel.

For example, the alloyed magnetic particles comprise FeCo alloy, FeNi alloy, CoNi alloy, or FeCoNi alloy, and so on. In the above mentioned alloys, the mass percent of each components is not particularly limited.

For example, the magnetic particles are spherical or near-spherical. As compared with shapes, such as, scaly, dendritic, etc., in a case that each of the magnetic particles is spherical, it is more conducive to the adsorption of the carriers. Thus, each of the magnetic particles is preferably spherical.

It should be noted that, a minor amount of magnetic particles may be in other shapes. During the preparation of the magnetic particles, the inhomogeneity of the shape and the size of the magnetic particles are unavoidable.

For example, each of the magnetic particles has a particle size or an equivalent particle size of 1 nm to 10 nm. For example, each of the magnetic particles has the particle size or the equivalent particle size of 1 nm, 2 nm, 4 nm, 6 nm, 8 nm, or 10 nm.

It should be noted that, in the process of synthesizing the magnetic particles, the particle size of the magnetic particles is not uniform. Those magnetic particles within a certain size range outside the above-mentioned size range are also covered by the protection scope of embodiments of the present disclosure.

For example, the carriers are made of at least one of carbon black, activated carbon, and carbon nanotube. For example, the carriers have adsorbing pores, and the magnetic particles can enter the adsorbing pores to reduce the agglomeration of magnetic particles.

It should be noted that, the carbon black, the activated carbon and the carbon nanotube usually have relatively large specific surface area, appropriate pore structures and surface micro-structure, and have stronger adsorption capacity for the adsorbents thereon. It should be noted that, the carriers refer to geometric bodies having certain shapes within a certain size range. The certain size as mentioned herein is usually between millimeter and nanometer. Thus, the above mentioned carriers refer to particles having smaller order of size. Each of the particles has a specific micro-shape including, but not limited to a sphere or a tube, and may be in various other shapes, which are not limited herein.

For example, the carbon black is generally black powdered substances obtained by incomplete combustion or pyrolysis of hydrocarbons under a certain controlled process condition. The main component of the carbon black is carbon, and the carbon black also comprises a small amount of elements such as oxygen, hydrogen and sulfur. The particle of the carbon black is appropriately spherical, and the particle of the carbon black has a size of 0.05 μm to 0.1 μm.

For example, the activated carbon is black powdered amorphous carbon, massive amorphous carbon, particulate amorphous carbon, or cellular amorphous carbon or crystalline carbon regularly arranged. The activated carbon has a good adsorption capacity for inorganic substances or organic substances in gas or solution and colloidal particles. The activated carbon has unique adsorptive surface structural characteristics and surface chemical properties. A mass percent of carbon in the activated carbon is from about 80% to 90%. In addition to the carbon, the activated carbon further comprises two type of admixtures: one is chemically bonded elements which are mainly oxygen and hydrogen, and the chemically bonded elements are left in the carbon due to incomplete carbonization, or introduced by chemical bonding of foreign non-carbon element with the surface of activated carbon during activation, for example, when activated by vapor, the surface of the activated carbon is oxidized, or the vapor is oxidized. The other type of admixture is ash, which is the inorganic component of the activated carbon.

For example, the carbon nanotube is a one-dimensional quantum material having a special structure (it has a radial dimension in nanometer order and an axial dimension in micron order, and both ends of the carbon nanotube are substantially sealed). The carbon nanotube is a co-axial circular tube consisting of several layers to tens of layers which are mainly composed of carbon atoms arranged in hexagon. A distance between the layers of the carbon nanotube is constant, for example, about 0.34 nm, and a diameter of the carbon nanotube is generally 10 nm to 20 nm.

For example, the various carriers as described above need to be modified. The carriers are modified to have organophilic functional groups on their surfaces. The organophilic functional groups enable the carriers to be better dispersed in the host flexible material without agglomeration. Meanwhile, more magnetic particles are adsorbed onto the organophilic functional groups. The magnetic particles are distributed on the carriers and the organophilic functional groups on the carriers, so that more magnetic particles are adsorbed onto the carriers, and the magnetic particles are better dispersed in the host flexible material.

For example, FIG. 3 is an enlarged schematic structural view of the carriers having magnetic particles adsorbed thereon. As illustrated in FIG. 3, the magnetic particles 22 are adsorbed on the surface of the carriers 23, which reduces the agglomeration of the magnetic particles 22, and meanwhile enables the magnetic particles 22 to be more homogeneously dispersed in the host flexible material.

For example, the magnetic particles 22 are adsorbed in the inner pores of the carriers 23. For example, the magnetic particles 22 are spherical or near-spherical with a micro shape, and the size of each of the magnetic particles 22 is less than the pore size of the carriers 23. Alternatively, a portion of the magnetic particles 22 are adsorbed into the inner pores and the micro-structures of the surface of the carriers 23, which means that the size of each of the magnetic particles 22 is close to the size of the pores and the micro-structures of the surface of the carriers 23. In this case, the micro-shape of each of the magnetic particles 22 is usually scaly or dendritic, which is not limited to this, as long as the magnetic particles 22 can be adsorbed onto the carriers 23 so that the adsorbed magnetic particles 22 are dispersed in the flexible base material by the carriers 23.

In the above mentioned flexible base materials provided by the embodiments of the present disclosure, the magnetic particles 22 are adsorbed onto the carriers 23 so that the magnetic particles 22 are relatively more homogeneously dispersed in the host flexible material by means of the carriers 23, which avoids agglomeration, particle size increase, or the like caused by directly dispersing the magnetic particles 22 in the host flexible material, and an overall magnetic property of the flexible base material is enhanced, and the bonding effect of the flexible base material used in an electronic component is improved.

At least one embodiment of the present disclosure further provides a preparation method of a flexible base material. For example, FIG. 4 is a flowchart of a preparation method of a flexible base material provided by an embodiment of the present disclosure. As illustrated in FIG. 4, the preparation method comprises:

S101: providing carriers;

S102: subjecting the carriers to a surface treatment thereby allowing the carriers to have organophilic functional groups on their surfaces;

S103: adsorbing magnetic particles onto the carriers;

S104: dispersing the carriers having the magnetic particles adsorbed thereon in a host flexible material.

For example, the carriers are made of at least one of carbon black, activated carbon, and carbon nanotube. The properties of the carbon black, the activated carbon and the carbon nanotube refer to the relevant descriptions mentioned above, which are omitted herein.

For example, adsorbing the magnetic particles onto the carriers comprising: dispersing the magnetic particles into a first solvent to form a dispersion of the magnetic particles; dispersing the carriers into the dispersion of the magnetic particles to adsorb the magnetic particles; separating the carriers having the magnetic particles adsorbed thereon from dispersion liquor in the dispersion of the magnetic particles; drying the carriers to obtain dried carriers having the magnetic particles adsorbed thereon.

For example, ultrasonic dispersion is used to increase the dispersion homogeneity of the magnetic particles in the first solvent and improve the adsorption efficiency of the subsequent carriers.

For example, the first solvent plays the roles of preventing the magnetic particles from sedimentation and agglomeration, and forming a stable dispersion. For example, the first solvent is a common dispersing agent, such as, a polymer dispersant and the like. For example, methylpentanol, acetone, or ethanol, and so on.

For example, the carriers having the magnetic particles adsorbed thereon can be separated from the dispersion of the magnetic particles by a high-speed centrifuge.

For example, in the process of drying the carriers, the drying temperature and time should be flexibly adjusted in accordance with the quantity of the carriers for prevention of agglomeration of the carrier particles caused by occurrence of solid phase reaction at high temperature. For example, drying is carried out in a manner of gradual heating. For example, drying is carried out at reduced pressure.

For example, the carbon black carriers, the activated carbon carriers and the carbon nanotube carriers are converted to gaseous carbon dioxide upon heating at the high temperature. Thus, it can be demonstrated whether the carriers have the magnetic particles adsorbed thereon by ways of: baking the carriers obtained in accordance with Step S101 to S103 in a heating equipment, for example, a muffle furnace, to remove the carbon black, the activated carbon and the carbon nanotube, and the left solid materials which are materials of the magnetic particles. A test instrument, such as a Scanning Electron Microscope (SEM), can also be used to characterize detailed informations, such as, the presence or absence of the adsorbed magnetic particles on the surface of the carriers, and the distributed state of the adsorbed magnetic particles and so on.

For example, the carriers made of the carbon black, the activated carbon and the carbon nanotube have larger specific surface areas, appropriate pore structures and surface micro-structures, and thus have stronger adsorption capacity to the adsorbed materials. Due to an electrostatic adsorption effect, a lot of impurity ions may be adsorbed onto the surface of the carriers so that the adsorbing channels inside the carriers are blocked, and furthermore impurities are introduced into the subsequently formed flexible base material and affect the properties of the materials. Thus, it is required to modify the carriers to expose the adsorption channels inside the carriers and remove the impurities adsorbed on the carriers.

For example, modifying the carriers to expose the adsorption channels inside the carriers comprising: dispersing the carriers into an acidic solvent; separating the carriers from the acidic solvent; washing the carriers until a stable pH is achieved; and drying the carriers to obtain modified carriers.

For example, the acidic solvent is a common modifying agent, such as, nitric acid. The reaction time and temperature are flexibly adjusted according to different carriers and acidic solvents, which are not limited herein.

For example, modifying the carriers further comprises: placing the carriers in an oven, and performing drying activation at a temperature of 120° C. to expose the adsorption channels inside the carriers. As the carriers may agglomerate to a lesser extent during drying, they can be gently rolled with a glass rod to reduce its agglomeration degree.

It should be noted that, the pH is a value indicating an acid and alkali degree of a solution. “Washing the carriers until a stable pH is achieved” means washing the carriers by deionized water, until the pH of the deionized water after washing does not change or changes in a very minor range. After the stable pH is achieved, the pH is correspondingly stabilized in a slightly acidic range.

For example, factors like the material ratios, the concentrations of the modifying agent (i.e., the acidic solvent), the rotation speed of stirring, the reaction time, the reaction temperature, the activation temperature, the time, and the like during the above mentioned process affect the effect of the surface modification of the carriers. The modification effects are flexibly adjusted in accordance with various factors mentioned above, which are not particularly limited herein.

For example, the subjecting the carriers to a surface treatment thereby allowing the carriers to have organophilic functional groups on their surfaces comprises: dispersing the carriers into a second solvent; heating the second solvent having the carriers dispersed therein; adding a solution comprising the organophilic functional groups to the second solvent; separating the carriers; and drying the carriers to obtain the carriers having the organophilic functional groups on their surfaces.

For example, the carriers are subject to a surface treatment to allow the carriers to have organophilic functional groups on their surface, and the organophilic functional groups are used for homogeneously dispersing the carriers in the host flexible material, and allowing more magnetic particles to be adsorbed onto the carriers.

For example, the second solvent plays the roles of preventing the carriers from sedimentation and agglomeration, and forming a stable dispersion. For example, the second solvent is methylpentanol.

The following description is made by taking the organophilic functional groups comprising at least one of amino, mercapto, vinyl, epoxy, cyano, carboxyl, and methacryloyloxy as an example.

A certain mass of carriers such as the carbon black, the activated carbon, and the carbon nanotube and so on are added into a 3-neck flask, followed by adding an appropriate volume of a second solvent. The carriers are dispersed by ultrasonic shaking. Then, the second solvent having the carriers dispersed therein is heated with a heating jacket to a certain temperature under stirring at a certain rotation speed. A coupling agent, for example, a solution having organophilic functional groups, is slowly added to the stirred solution; and a suitable ratio of the coupling agent to the carriers is flexibly adjusted in accordance with the specific reaction. The mixture is washed by centrifuge to separate the second solvent, and the unreacted coupling agent or silane coupling agent from the particles of the carriers. The separated carriers are placed in a watch glass, which is in turned dried at a certain temperature in an oven to obtain particles of the carriers having organophilic functional groups on their surfaces.

For example, factors like the ratio of materials, the concentration of the second solvent, the rotation speed of stirring, the reaction time and the reaction temperature will all provide influences on the effect of forming organophilic functional groups on the surface of the carriers. The effect of modifying the carrier by the organophilic functional groups can be flexibly adjusted in accordance with various affecting factors as set forth, which are not particularly limited.

For example, the process of dispersing the carriers having magnetic particles adsorbed thereon into the host flexible material is: directly dispersing the carriers having the magnetic particles adsorbed thereon into the host flexible material in a liquid state, and then homogeneously mixing and solidifying the mixture to form the flexible base material. It should be noted that, in a case that the host flexible material is liquid, the host flexible material need to have a certain solubility in the solvent so that it can be applied by knife coating, followed by removal of the solvent under vacuum and two-stage heating solidification, and finally form a flexible base having the desired thickness. Alternatively, the magnetic particles may be homogeneously mixed with monomers for forming the flexible material, and then form the flexible base material by polymerization.

At least one embodiment of the present disclosure further provides a flexible substrate. For example, FIG. 5 is a schematic view of a flexible substrate provided by an embodiment of the present disclosure. As illustrated in FIG. 5, a flexible substrate 30 comprises a flexible base substrate 31 made of any one of the above mentioned flexible base materials and a thin film transistor 32 formed on the flexible base substrate 31. For example, the thin film transistor 32 is either a bottom-gate thin film transistor, or a top-gate thin film transistor.

For example, FIG. 6 is a cross-sectional schematic structural view of a flexible substrate provided by an embodiment of the present disclosure. FIG. 6 takes a bottom-gate thin film transistor as an example. As illustrated in FIG. 6, the flexible substrate comprises: a flexible base substrate 31; and a gate electrode layer 321, a gate insulating layer 322, an active layer 323 and a source-drain electrode 324 positioned on the flexible base substrate 31. The source-drain electrode layer 324 comprises a source electrode 3241 and a drain electrode 3242. A passivation layer 525 is formed on the source electrode 3241 and the drain electrode 3242. Via holes are formed in the passivation layer 325. Pixel electrodes 326 are formed on the passivation layer 325, and the pixel electrodes 326 are electrically connected with the drain electrode 3242 by the via holes in the passivation layer 325.

For example, various layers of the thin film transistor are prepared in accordance with conventional methods, and a thickness of each film layer refers to conventional thickness design, which is omitted herein.

For example, the difference between the top-gate thin film transistor and the bottom-gate thin film transistor only relies in that in the bottom-gate thin film transistor, the gate electrode layer 321 is positioned at the side of the active layer 323 close to the flexible base substrate 31; and in the top-gate thin film transistor, the active layer 323 is positioned at the side of the gate electrode layer 321 close to the flexible base substrate 31. The specific design of various layers of the thin film transistor can refer to the relevant descriptions of the bottom-gate thin film transistor as set forth above, which are omitted herein.

For example, an organic light-emitting diode is formed on the thin film transistor. The organic light-emitting diode comprises a first electrode, a hole injection layer, a hole transport layer, a quantum dot light-emitting layer, an electron injection layer, an electron transport layer, and a second electrode, which are stacked in an order from the bottom to the top. The first electrode can be the pixel electrode of the thin film transistor as set forth above.

For example, FIG. 7 is a cross-sectional schematic structural view of a flexible substrate provided by an embodiment of the present disclosure. As illustrated in FIG. 7, on the basis of the structure as illustrated in FIG. 6, an organic insulating layer 33 is positioned between the flexible base substrate 31 and the thin film transistor 32. The organic insulating layer 33 prevents the magnetic particles in the flexible base substrate from diffusing to the active layer of the thin film transistor, thereby avoids the influence on the properties of the thin film transistor. Meanwhile, the organic insulating layer 33 is flexible, which can not reduce the flexibility of the flexible base substrate.

For example, as illustrated in FIG. 7, an inorganic insulating layer 34 is disposed between the organic insulating layer 33 and the thin film transistor 32. The inorganic insulating layer 34 is used for encapsulating so as to prevent moisture from entering into the organic light emitting diodes, thereby the influence on the properties of the OLEDs is avoided.

At least one embodiment of the present disclosure further provides a preparation method of a flexible substrate. For example, FIG. 8 is a flowchart of a preparation method of a flexible substrate provided by an embodiment of the present disclosure. As illustrated in FIG. 8, the preparation method comprises:

S201: providing a glass substrate;

S202: forming a magnetic layer on the glass substrate;

S203: forming a flexible base substrate on the magnetic layer by using a flexible base material;

S204: forming a thin film transistor on the flexible base substrate;

S205: treating the magnetic layer and the flexible base substrate to eliminate a magnetic force between the magnetic layer and the flexible base substrate; and

S206: removing the glass substrate and the magnetic layer to obtain the flexible substrate.

For example, materials of the magnetic layer comprise at least one of SmCo magnet, NdFeB magnet, ferrite magnet, AlNiCo magnet and FeCrCo magnet.

For example, the magnetic particles are spherical or near-spherical. As compared with shapes, such as, scaly, dendritic, etc., in a case that each of the magnetic particles is spherical, it is more conducive to the adsorption of the carriers. Thus, each of the magnetic particles is preferably spherical. Moreover, the spherical or near-spherical magnetic particles allow the whole flexible base materials to have more homogeneous distributed magnetic property as compared with the magnetic particles in other shapes.

For example, each of the magnetic particles has a particle size or an equivalent particle size of 1 nm to 10 nm. For example, each of the magnetic particles has the particle size or the equivalent particle size of 1 nm, 2 nm, 4 nm, 6 nm, 8 nm, or 10 nm.

For example, the treating the magnetic layer and the flexible base substrate to eliminate the magnetic force between the magnetic layer and the flexible base substrate comprises: eliminating the magnetic force between the magnetic layer and the flexible base substrate by means of applying an external force, heating, or applying an electric field.

For example, the external force is an external force applied by a mechanical arm to rigidly separate the magnetic layer from the flexible base substrate, as long as the external force is greater than the magnetic force between the magnetic layer and the flexible base substrate.

For example, heating is used to eliminate the magnetic force between the magnetic layer and the flexible base substrate. The heating temperature is from 300° C. to 500° C., and the heat-resistance temperature of the host flexible material in accordance with the embodiments of the present disclosure is preferably about 500° C. Thus, the heating temperature for eliminating the magnetic force between the magnetic layer and the flexible base substrate is generally not higher than 500° C. According to the heat-resistance temperatures of different host flexible materials, the heating temperature can be accordingly adjusted, which is not limited herein.

For example, an electric field is applied to eliminate the magnetic force between the magnetic layer 40 and the flexible base substrate 31. For example, FIG. 9 is a schematic view of applying an electric field to eliminate the magnetic force between the magnetic layer and the flexible base substrate provided by an embodiment of the present disclosure. As illustrated in FIG. 9, the process of applying an electric field comprises: arranging electrodes on both sides of the magnetic layer 40, and then applying an electric field to the electrodes to change the arrangement of inner atoms of the magnetic layer 40, so as to eliminate the magnetism thereof. For example, the material of the electrodes is indium tin oxide (ITO). After the electric field is applied in such manner, the magnetic layer 40 is easy to be separated from the glass substrate 50.

For example, the preparation method further comprises: forming an organic insulating layer between the flexible base substrate and the thin film transistor. For example, the materials of the organic insulating layer are organic insulating materials, such as, polyimide, acrylate, epoxy, or polymethylmethacrylate. The insulating layer is formed by a process such as a chemical vapor deposition method, a spin coating method, or a printing method and so on.

For example, the preparation method further comprises: forming an inorganic insulating layer between the organic insulating layer and the thin film transistor. The materials of the inorganic insulating layer comprise oxides or nitrides or oxynitrides of silicon, for example, silicon oxide, silicon nitride, silicon oxynitride; or aluminum oxide, titanium nitride, or other oxynitrides of metals.

The flexible base material, the preparation method of the flexible base material, the flexible substrate and the preparation method of the flexible substrate have at least one of the following benefits.

(1) The preparation method of the flexible substrate provided by at least one embodiment of the present disclosure, the magnetic layer on the glass substrate is closely attached to the flexible base substrate by a magnetic force, and then the glass substrate is separated from the flexible base substrate by means of applying an external force, heating or demagnetizing, which avoids adverse effects on the active layer and the flexible base substrate caused by the laser irradiation separation.

(2) The preparation method of the flexible substrate provided by at least one embodiment of the present disclosure is simple and easy to operate without any influence on the functional layers.

The following points required to be explained:

(1) the drawings of the embodiments of the present disclosure only relate to the structures related to the embodiments of the present disclosure, and other structures can refer to the general design.

(2) for the sake of clarity, in the drawings used to describe the embodiments of the present disclosure, the thickness of layers or areas is enlarged or reduced, that is, the drawings are not drawn according to the actual scale. It is understood that in the case that an element such as a layer, membrane, region, or substrate is referred to as being “up” or “down” on another element, the element may be “directly” “on” or “down” on another element or there may be intermediate elements.

(3) without conflict, the embodiments of the present disclosure and the features in the embodiments may be combined with each other to obtain new embodiments.

What are described above is related to only the illustrative embodiments of the present disclosure and not limitative to the protection scope of the present application. Therefore, the protection scope of the present application shall be defined by the accompanying claims.

1. A flexible base material, comprising:
a host flexible material; and
carriers dispersed in the host flexible material and having magnetic particles adsorbed thereon; wherein the carriers have organophilic functional groups on their surface.

2. The flexible base material according to claim 1, wherein the host flexible material comprises polyetheretherketone, polyarylester, fluorinated polyimide, polyimide, polycarbonate, polyethylene, polyacrylate, polyarylate, polyetherimide, polyethersulfone, polyethylene terephthalate, polypropylene, polysulfone, polymethylmethacrylate, cellulose triacetate, cycloolefin polymer, cellulose acetate propionate, polyethylene naphthalene dicarboxylate, polyphenylene sulfide, or cycloolefin copolymer.

3. The flexible base material according to claim 1, wherein the organophilic functional groups comprise at least one of amino, mercapto, vinyl, epoxy, cyano, carboxyl, and methacryloyloxy.

4. The flexible base material according to claim 1, wherein the magnetic particles comprise an elemental metal or alloy of iron, cobalt, or nickel.

5. The flexible base material according to claim 1, wherein the magnetic particles are spherical or near-spherical.

6. The flexible base material according to claim 1, wherein the carriers are made of at least one of carbon black, activated carbon, and carbon nanotube.

7. A preparation method of a flexible base material, comprising:
forming carriers having magnetic particles adsorbed thereon; and
dispersing the carriers having magnetic particles adsorbed thereon into a host flexible material;
wherein before dispersing the carriers having magnetic particles adsorbed thereon into the host flexible material, the preparation method further comprises:
subjecting the carriers to a surface treatment thereby allowing the carriers to have organophilic functional groups on their surfaces.

8. The preparation method according to claim 7, wherein the forming carriers having magnetic particles adsorbed thereon comprises:
dispersing the magnetic particles into a first solvent to form a dispersion of the magnetic particles;
dispersing the carriers into the dispersion of the magnetic particles to adsorb the magnetic particles;
separating the carriers from dispersion liquor in the dispersion of the magnetic particles; and
drying the carriers to obtain the carriers having magnetic particles adsorbed thereon.

9. The preparation method according to claim 7, wherein before forming the carriers having the magnetic particles adsorbed thereon, the preparation method further comprises: modifying the carriers to expose adsorbing channels inside the carriers.

10. The preparation method according to claim 9, wherein the modifying the carriers to expose adsorbing channels inside the carriers comprises:
dispersing the carriers into an acidic solvent;
separating the carriers from the acidic solvent;
washing the carriers until a stable pH is achieved; and
drying the carriers to obtain modified carriers.

11. The preparation method according to claim 7, wherein the subjecting the carriers to a surface treatment thereby allowing the carriers to have organophilic functional groups on their surfaces comprises:
dispersing the carriers into a second solvent;
heating the second solvent having the carriers dispersed therein;
adding a solution comprising the organophilic functional groups to the second solvent;
separating the carriers; and
drying the carriers to obtain the carriers having the organophilic functional groups on their surfaces.

12. A flexible substrate, comprising:
a flexible base substrate made of the flexible base material according to claim 1, and
a thin film transistor formed on the flexible base substrate.

13. The flexible substrate according to claim 12, wherein an organic insulating layer is arranged between the flexible base substrate and the thin film transistor.

14. The flexible substrate according to claim 13, wherein an inorganic insulating layer is arranged between the organic insulating layer and the thin film transistor.

15. A preparation method of a flexible substrate, comprising:
providing a glass substrate;
forming a magnetic layer on the glass substrate;
forming a flexible base substrate on the magnetic layer by using the flexible base material according to claim 1; and
forming a thin film transistor on the flexible base substrate;
treating the magnetic layer and the flexible base substrate to eliminate a magnetic force between the magnetic layer and the flexible base substrate; and
removing the glass substrate and the magnetic layer to obtain the flexible substrate.

16. The preparation method according to claim 15, wherein materials of the magnetic layer comprise at least one of SmCo magnet, NdFeB magnet, ferrite magnet, AlNiCo magnet and FeCrCo magnet.

17. The preparation method according to claim 15, wherein the treating the magnetic layer and the flexible base substrate to eliminate the magnetic force between the magnetic layer and the flexible base substrate comprises: eliminating the magnetic force between the magnetic layer and the flexible base substrate by means of applying an external force, heating, or applying an electric field.

18. The preparation method according to claim 15, further comprising: forming an organic insulating layer between the flexible base substrate and the thin film transistor.

19. The preparation method according to claim 18, further comprising: forming an inorganic insulating layer between the organic insulating layer and the thin film transistor.
